(19) United States
(12) Patent Application Publication
(10) Pub. No.: US 2026/0039195 A1
(43) Pub. Date: Feb. 5, 2026

(54) LOAD LINE COMPENSATION FOR A POWER SUPPLY CIRCUIT

(71) Applicant: QUALCOMM Incorporated, San Diego, CA (US)

(72) Inventors: Chengyue YU, Irvine, CA (US); Navankur BEOHAR, Chandler, AZ (US); Edgar MARTI-ARBONA, Chandler, AZ (US); Joseph Dale RUTKOWSKI, Chandler, AZ (US)

(21) Appl. No.: 18/788,659

(22) Filed: Jul. 30, 2024

(51) Int. Cl. H02M 3/156; H03K 19/0175

(52) U.S. Cl. CPC H02M 3/156; H03K 19/017509

(57) ABSTRACT

Certain aspects of the present disclosure generally relate to power supply circuits and techniques for load voltage drop compensation. An example power supply circuit generally includes: a power stage coupled between the power stage and an output node of the power supply circuit; a feedback circuit coupled to the output node of the power supply circuit and including a feedback node; a level-shifter circuit including an input coupled to the feedback node; and a first current source coupled between the level-shifter circuit and a node of the feedback circuit.

### TECHNICAL FIELD

Certain aspects of the present disclosure generally relate to electronic circuits and, more particularly, to power supply circuits and techniques for load voltage drop compensation.

### BACKGROUND

A voltage regulator may provide a constant direct current (DC) output voltage regardless of changes in load current or input voltage. Voltage regulators may be classified as linear regulators or switching regulators. While linear regulators tend to be relatively compact, many applications may benefit from the increased efficiency of a switching regulator. A linear regulator may be implemented by a low-dropout (LDO) regulator, for example. A switching regulator (also known as a “switching converter” or “switcher”) may be implemented, for example, by a switched-mode power supply (SMPS), such as a buck converter, a boost converter, a buck-boost converter, or a charge pump.

For example, a buck converter is a type of SMPS that may include: (1) a high-side switch coupled between a relatively higher voltage rail and a switching node, (2) a low-side switch coupled between the switching node and a relatively lower voltage rail, (3) and an inductor coupled between the switching node and a load. The high-side and low-side switches are typically implemented with transistors, although the low-side switch may alternatively be implemented with a diode.

Power management integrated circuits (power management ICs or PMICs) are used for managing the power scheme of a host system and may include and/or control one or more voltage regulators (e.g., buck converters and/or LDOs). A PMIC may be used in battery-operated devices, such as mobile phones, tablets, laptops, wearables, etc., to control the flow and direction of electrical power in the devices. The PMIC may perform a variety of functions for the device, such as DC-to-DC conversion (e.g., using a voltage regulator as described above), battery charging, power-source selection, voltage scaling, power sequencing, etc.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure are directed towards a power supply circuit. The power supply circuit generally includes: a power stage coupled between the power stage and an output node of the power supply circuit; a feedback circuit coupled to the output node of the power supply circuit and including a feedback node; a level-shifter circuit having an input coupled to the feedback node; and a first current source coupled between the level-shifter circuit and a node of the feedback circuit.

Certain aspects of the present disclosure are directed towards a method for power supply control. The method generally includes: generating a feedback voltage based on an output voltage of a power supply circuit; performing a voltage level shift based on the feedback voltage to yield a level-shifted feedback voltage representing a load current of the power supply circuit; and adjusting the feedback voltage based on the level-shifted feedback voltage.

Certain aspects of the present disclosure are directed towards a load line compensation (LLC) circuit. The LLC circuit generally includes: a level-shifter circuit configured to perform a voltage level shift based on a feedback voltage for a power supply circuit to yield a level-shifted feedback voltage representing a load current of the power supply circuit; and a current source configured to adjust the feedback voltage based on the level-shifted feedback voltage.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a block diagram of an example device that includes a power supply system with at least one switched-mode power supply (SMPS) circuit, in which aspects of the present disclosure may be practiced.

FIG. 2 illustrates a regulator configured to compensate for a voltage drop across a cable or trace, in accordance with certain aspects of the present disclosure.

FIG. 3 illustrates a power supply circuit including a power stage and a feedback circuit, in accordance with certain aspects of the present disclosure.

FIGS. 4A and 4B illustrate a circuit diagram of an example load line compensation (LLC) circuit, in accordance with certain aspects of the present disclosure.

FIG. 5 is a flow diagram illustrating example operations for power supply control, in accordance with certain aspects of the present disclosure.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Certain aspects of the present disclosure are directed toward a power supply circuit implemented with load line compensation (LLC). As used herein, compensating for a voltage drop (e.g., across a cable) generally refers to adjusting an output voltage of a power supply circuit to at least partly compensate for the voltage drop. In some aspects, load line compensation may be implemented by identifying an amount of load current for the power supply circuit and adjusting the output voltage of the power supply circuit based on the load current and a configured resistance associated with the load (e.g., resistance associated with a cable delivering power to the load). A feedback circuit for the power supply voltage may generate a feedback voltage that indicates the power supply's load current in addition to an offset voltage. A level-shifter circuit may be used to generate a level-shifted feedback voltage based on the feedback voltage to compensate for the offset voltage so that the level-shifted feedback voltage represents the load current. Based on the level-shifted feedback voltage representing the load current, the feedback voltage generated by the feedback circuit may be adjusted, resulting in the output voltage of the power supply circuit being adjusted to compensate for the voltage drop (across the cable). Thus, some aspects provide an open loop-based scheme for voltage drop compensation based on a preset routing resistance (e.g., cable resistance). The compensation scheme described herein is referred to as “open loop” because the scheme does not use a sense line (e.g., across the cable) to feed back the voltage at the load to the power supply circuit. The compensation scheme described herein uses load information obtained through a current-sensing loop and controls the power supply output voltage in a linear manner, making the scheme flexible (e.g., applicable to any suitable cable for power delivery to the load) and cost-efficient.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

It should be understood that aspects of the present disclosure may be used in a variety of applications. Although the present disclosure is not limited in this respect, the circuits disclosed herein may be used in any of various suitable apparatuses, such as in the power supply, battery charging circuit, or power management circuit of a communication system, a video codec, audio equipment such as music players and microphones, a television, camera equipment, and test equipment such as an oscilloscope. Communication systems intended to be included within the scope of the present disclosure include, by way of example only, cellular radiotelephone communication systems, satellite communication systems, two-way radio communication systems, one-way pagers, two-way pagers, personal communication systems (PCS), personal digital assistants (PDAs), and the like.

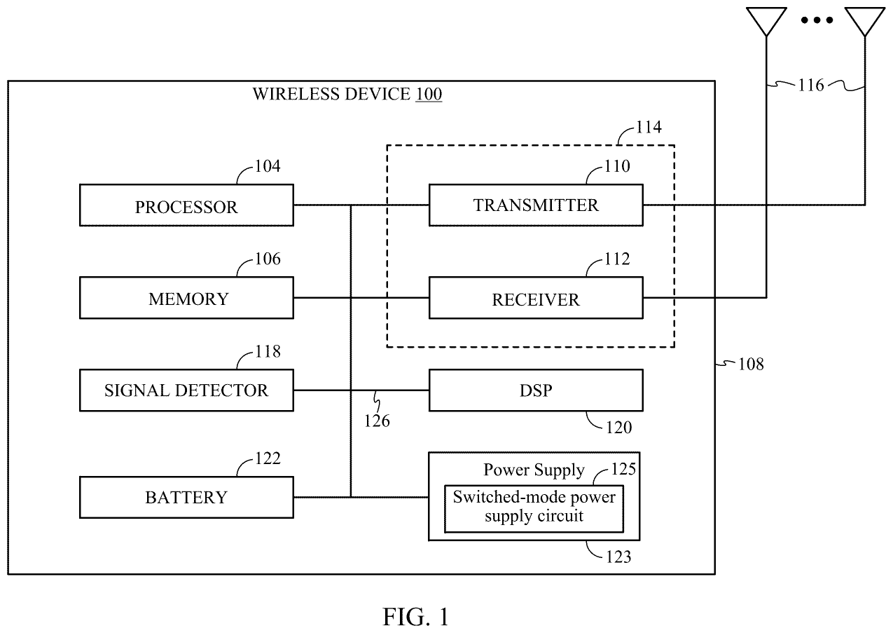

FIG. 1 illustrates an example device 100 in which aspects of the present disclosure may be implemented. The device 100 may be a battery-operated device such as a cellular phone, a PDA, a handheld device, a wireless device, a laptop computer, a tablet, a smartphone, an Internet of things (IoT) device, a wearable device, a virtual reality (VR) or augmented reality (AR) device, etc.

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114. The device 100 may also include (not shown) multiple transmitters, multiple receivers, and/or multiple transceivers.

The device 100 may also include a signal detector 118 that may be used in an effort to detect and quantify the level of signals received by the transceiver 114. The signal detector 118 may detect such signal parameters as total energy, energy per subcarrier per symbol, and power spectral density, among others. The device 100 may also include a digital signal processor (DSP) 120 for use in processing signals.

The device 100 may further include a battery 122, which may be used to power the various components of the device 100 (e.g., when the device is disconnected from an external power source). The device 100 may also include a power supply system 123 for managing the power from the battery (or from one or more power ports for receiving external power) to the various components of the device 100. At least a portion of the power supply system 123 may be implemented in one or more power management integrated circuits (power management ICs or PMICs) The power supply system 123 may perform a variety of functions for the device 100 such as DC-to-DC conversion, battery charging, power-source selection, voltage scaling, power sequencing, etc. For example, the power supply system 123 may include one or more power supply circuits, which may include a switched-mode power supply circuit 125. In some cases, the switched-mode power supply circuit 125 may be connected to a load through a cable, such as a flex cable that has substantial resistance. In some aspects, load line compensation (LLC) may be used to compensate (or at least adjust) for a voltage drop across the cable or any resistive component, as described in more detail herein.

The various components of the device 100 may be coupled together by a bus system 126, which may include a power bus, a control signal bus, and/or a status signal bus in addition to a data bus. Additionally or alternatively, various combinations of the components of the device 100 may be coupled together by one or more other suitable techniques.

### Example Techniques for Voltage Drop Compensation

Certain aspects of the present disclosure are directed towards compensating (or at least adjusting) for a voltage drop associated with routing from a power supply circuit output to a load, such as a display panel. In some implementations, the output voltage of the power supply circuit may be provided to the load (e.g., display panel) using a flexible cable (also referred to herein as a “flex cable”). The flex cable may have significant resistance, causing a voltage drop (e.g., current times resistance (IR) drop) across the cable. Thus, the voltage at the display panel may be decreased, which may adversely impact the operation of the display. Due to the sensitivity of the panel brightness to supply voltage, the IR drop may be compensated for to provide a more consistent voltage for the display. Although some examples provided herein are described with respect to a display panel, the techniques described herein may be applied for load line compensation for any suitable load.

In some implementations, a sense pin may be provided in a plug of the flex cable, and a sense line may be routed through the flex cable to provide voltage feedback to the power supply circuit representing the voltage at the load. With the voltage feedback, the output voltage of the power supply circuit may be regulated to provide a specific voltage at the load. However, implementing a sense pin and sense line via the flex cable may be costly, may result in increased area consumption, and may be troublesome with regard to feedback voltage stability due to high parasitics (e.g., parasitic inductance) along the cable. Certain aspects of the present disclosure are directed towards an open-loop-based scheme for IR drop compensation based on a preset of routing resistance. Thus, the IR drop compensation may be performed without implementing a feedback line from the load (e.g., a sense line through the cable).

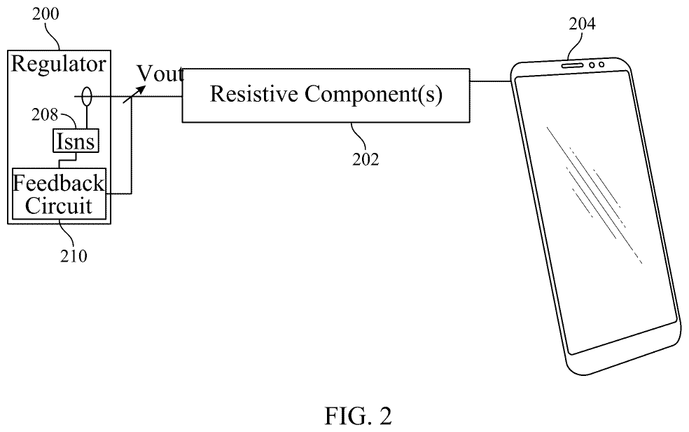

FIG. 2 illustrates a regulator 200 configured to compensate for an IR drop across a resistive component 202 such as a cable or any trace of printed circuit board (PCB), in accordance with certain aspects of the present disclosure. As shown, the regulator may generate an output voltage (Vout) that may be provided to a display panel 204 via the cable. The regulator 200 may include a feedback circuit 210 that may receive a feedback voltage representing Vout. The feedback voltage may be used by the regulator 200 to regulate Vout. In some aspects, the load current (e.g., output current) of the regulator may be sensed via a current-sensing (Isns) circuit 208 and used to adjust the feedback voltage for the regulator. In some cases, the load current may be derived from the feedback voltage from the feedback circuit that may provide load current information. Suppose the load current increases, increasing IR drop across the resistive component 202. In that case, the feedback voltage may be decreased, resulting in the regulator attempting to increase Vout to at least partially compensate for the IR drop.

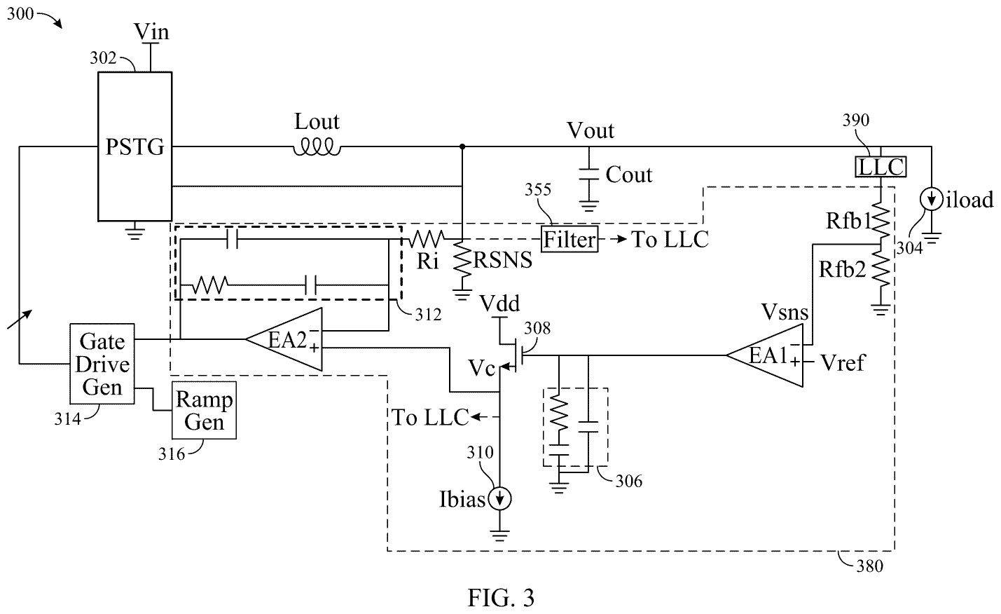

FIG. 3 illustrates a power supply circuit 300 including a power stage 302 (labeled “PSTG”) and a feedback circuit 380, in accordance with certain aspects of the present disclosure. The power stage 302 may include switches configured to direct current across an output inductive element (labeled “Lout”) to generate an output voltage Vout at a Vout node based on an input voltage Vin. Vout may be stored on an output capacitive element Cout. A load, represented by current source 304 with load current iload, may be coupled in shunt to the Vout node, as shown. In some aspects, feedback resistive elements Rfb1 and Rfb2 may form a voltage divider. A sense voltage (Vsns) node (also referred to as a “voltage divider node”) between Rfb1 and Rfb2 may be coupled to and provide Vsns to a negative input of a first error amplifier (labeled “EA1”), where a positive input of EA1 is coupled to a reference voltage (Vref) node. Vsns may be a voltage-divided version of Vout. In some aspects, a load line compensation (LLC) circuit 390 may be coupled between Rfb1 and the Vout node, as described in more detail herein.

A filter 306 may be coupled in shunt to the output of EA1, as shown. The output of EA1 may be coupled to a gate of a transistor 308 (e.g., an n-type transistor, as shown). A drain of the transistor 308 may be coupled to a voltage rail Vdd. A current source 310 may be coupled to and sink a bias current (Ibias) from a source of the transistor 308. A voltage Vc at the source of transistor 308 may indicate the average of Vsns plus an offset voltage. Vout and Vsns change dynamically with respect to load current (iload). Thus, Vc also provides average load current information (e.g., represents the average of iload) with an additional offset voltage. As will be described in more detail herein, a level shifter circuit may be used to perform a voltage reduction to compensate for at least a portion of this additional offset voltage, effectively providing a level-shifted feedback voltage that provides the load current information (e.g., without the additional offset voltage).

In some cases, the power supply circuit may be implemented with a current loop. For example, a portion of the inductor current may be sensed and converted to a current sensing voltage (V_{ISNS}) via a sense resistive element RSNS. While FIG. 3 shows the inductor current being sensed at a terminal of the inductive element Lout, current sensing may be performed at any suitable node of the power supply circuit such as within the power stage 302. An input resistive element Ri may be coupled between RSNS and a filter 312. The filter 312 may be coupled between a negative input of a second error amplifier EA2 and an output of EA2. A positive input of EA2 may be coupled to the source of transistor 308 and receive Vc. EA2 facilitates current control for the power supply circuit 300. EA2 may be used to control a gate drive generator 314. Based on the EA2 output voltage and a ramp signal generated via a ramp generator 316, the gate drive generator 314 may be used to drive the gates of one or more switches of the power stage 302 for voltage regulation (e.g., regulating Vout).

While the power supply circuit 300 is described with respect to feedback circuitry implemented with voltage and current control of the power stage, certain aspects of the present disclosure may be implemented for a power supply circuit with any suitable feedback circuit. For example, the LLC circuit 390 may receive any suitable feedback voltage representing an output current (e.g., load current) of the power supply circuit 300. The feedback voltage may be Ve or V_{ISNS}, in some cases. For instance, the LLC circuit 390 may receive V_{ISNS} through a filter 355 (e.g., a low-pass filter (LPF)) that may be used to perform LLC, as described in more detail herein.

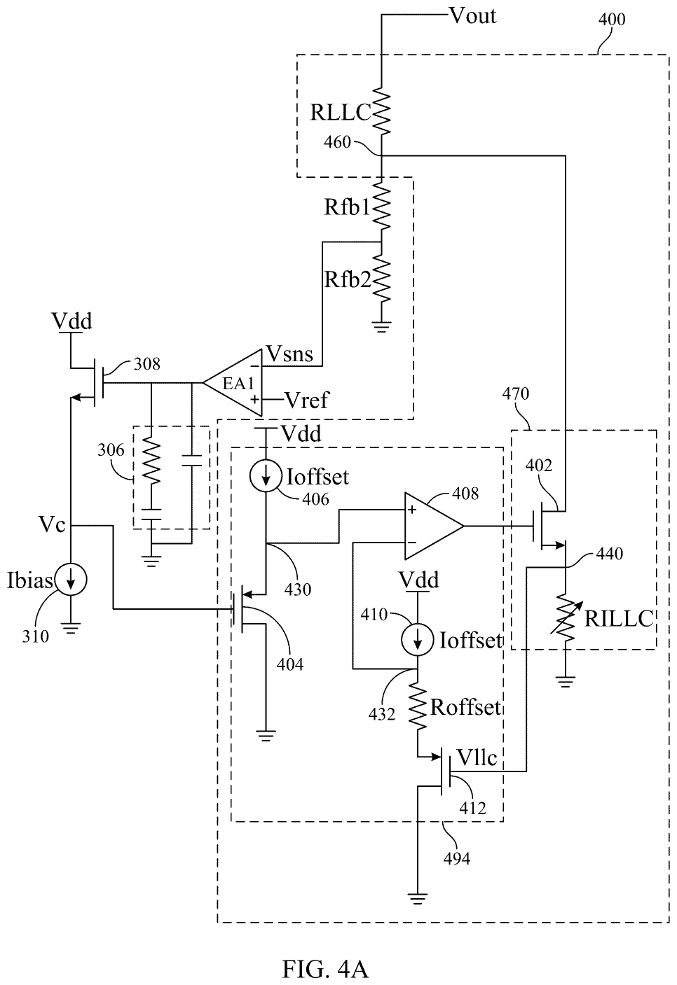

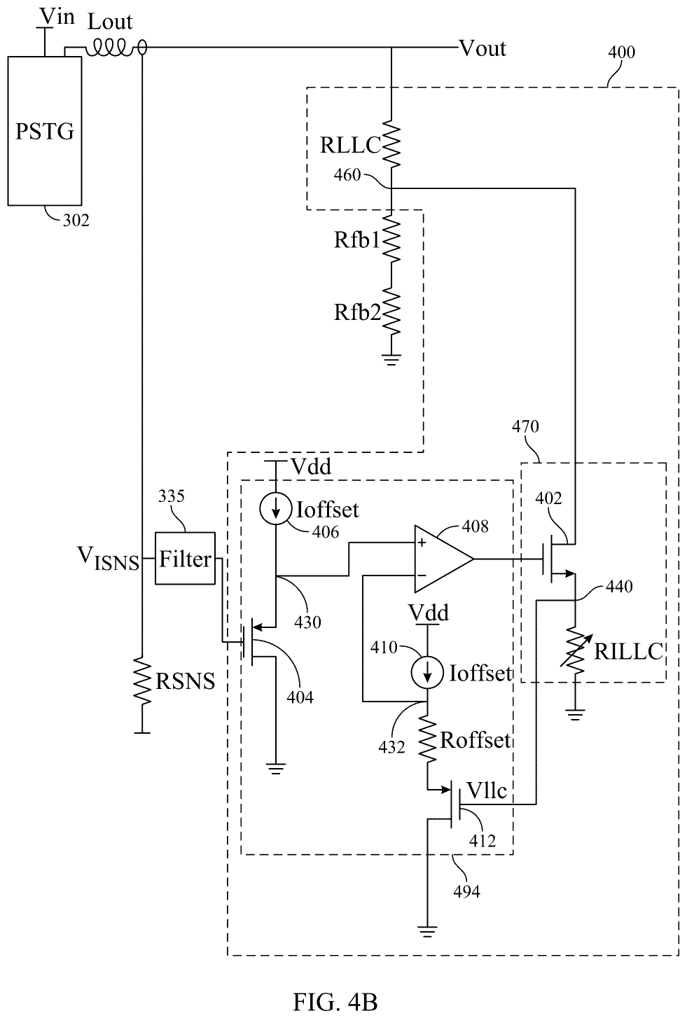

FIG. 4A illustrates an example LLC circuit 400, in accordance with certain aspects of the present disclosure. As shown, the LLC circuit 400 may correspond to the LLC circuit 390 shown in FIG. 3. As shown, the LLC circuit 400 may include an LLC resistive element (RLLC) coupled between Rfb1 and the Vout node. The node 460 between RLLC and Rfb1 may be coupled to a current source 470 that may be used to sink a current from RLLC causing a voltage drop across RLLC, decreasing Vsns. The current sunk from RLLC via the current source 470 may correspond to iload as described herein. As iload increases, the amount of current sunk from RLLC may be increased, decreasing Vsns. As a result, the feedback voltage of the power supply circuit 300 may be decreased so that the power supply circuit 300 attempts to increase Vout, in effect at least partly compensating for a voltage drop across the resistive component 202. As shown, the current source 470 may be implemented via a transistor 402 having a source coupled to a resistive element (RILLC).

The LLC circuit 400 may include a level-shifter circuit 494 configured to generate a level-shifted signal based on Vc representing iload. The level-shifter circuit 494 may include a transistor 404 (e.g., a p-type transistor) having a gate coupled to a source of transistor 308. A drain of transistor 404 may be coupled to a reference potential node (e.g., electric ground), and a source of the transistor 404 may be coupled to a current source 406 providing an offset current (Ioffset), generating a voltage at a positive input of an amplifier 408. The node 430 between the current source 406 and transistor 404 may be coupled to the positive input of the amplifier 408. The current source 406 and transistor 404 form a voltage follower circuit (also referred to as a “source follower circuit”). The negative input of the amplifier 408 may be coupled to a node 432 between a current source 410 and a resistive element (Roffset). A source of a transistor 412 (e.g., a p-type transistor) may be coupled to Roffset, and a drain of transistor 412 may be coupled to the reference potential node (e.g., electric ground). In some aspects, a gate of transistor 412 is coupled to a node 440 between a resistive element (RILLC) and a transistor 402. The output of the amplifier 408 may be coupled to a gate of transistor 402 (e.g., an n-type transistor). The amplifier 408 may control the drain-to-source current of the transistor 402 such that the voltages at nodes 430, 432 are equal. An LLC voltage (Vllc) may be generated at node 440, that may be a level-shifted version of Vc. Vllc may be calculated per the following equations:

$$Vllc = Vc - Voffset$$

$$Voffset = Ioffset \times Roffset$$

As described, Vc provides average load current information (e.g., represents the average of iload) with an additional offset voltage. Voffset implemented by the level shifter circuit compensates (or at least adjusts) for at least a portion of this additional offset voltage, effectively providing a level-shifted voltage (Vllc) that represents iload.

The current sunk from the node 460 may be equal to Vllc divided by RILLC. RILLC may be set based on the load resistance (e.g., resistance of cable 202) to at least partially compensate for the IR drop across the cable 202 (or any resistive component). In some aspects, the transistors 404, 412 may have the same size. Ioffset may be set so that, when iload is equal to zero, Vllc is also equal to zero and little to no current is sunk from node 460. As the load current increases (e.g., resulting in increased IR drop across cable 202), the amount of current sunk from node 460 is increased, decreasing the feedback voltage of the LLC circuit 400 that in turn increases Vout, at least partially compensating for the IR drop.

Certain aspects implement load line compensation without using a sense line (e.g., without implementing cable 202 with a sense line). The LLC circuit 400 provide a stable design that may be implemented for different cable characteristics (e.g., cables having different resistances or any resistive components). RILLC is used to generate an offset current (e.g., current sunk from node 460) based on the load current information (e.g., based on Vllc). The offset current may be programmable (e.g., by adjusting the resistance of RILLC) based on the actual resistance of the cable 202. The LLC circuit 400 saves current as compared to conventional LLC implementations at low-load conditions.

An analog loop is used to generate a level-shifted version of Vout for LLC. Thus, an analog-to-digital converter (ADC), digital filter, and digital control circuitry may not be used but may be present in some other digital LLC implementations. The LLC circuit 400 may also provide continuous analog operations.

FIG. 4B illustrates the example LLC circuit 400 receiving the current sensing voltage (V_{ISNS}), in accordance with certain aspects of the present disclosure. For example, instead of receiving Vc as described with respect to FIG. 4A, the LLC circuit 400 may receive V_{ISNS} through the filter 355, which may be an LPF. Thus, the filtered version of V_{ISNS} may be provided to gate of the transistor 404. In this case, Vllc generated at node 440 may be a level-shifted version of the filtered version of V_{ISNS} used to perform LLC as described herein.

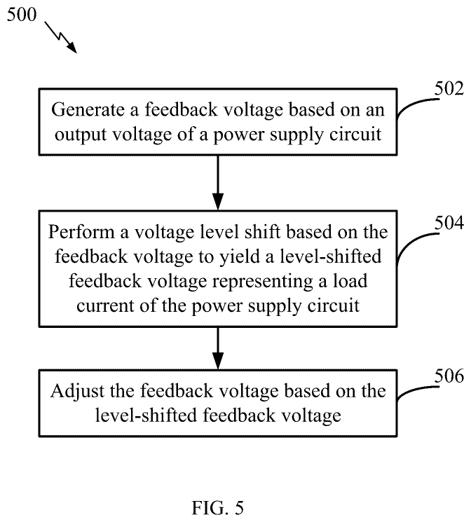

FIG. 5 is a flow diagram illustrating example operations 500 for power supply control, in accordance with certain aspects of the present disclosure. The operations 500 may be performed by a power supply circuit, such as the power supply circuit 300 of FIG. 3 including the LLC circuit 390 or LLC circuit 400 of FIG. 4A or FIG. 4B.

At block 502, the power supply circuit generates a feedback voltage (e.g., Vc shown in FIGS. 3 and 4 or V_{ISNS} or a filtered version of V_{ISNS}) based on an output voltage (e.g., Vout shown in FIGS. 3 and 4) of the power supply circuit. At block 504, the power supply circuit performs a voltage level shift (e.g., via the level-shifter circuit 494 of FIG. 4A or FIG. 4B) based on the feedback voltage to yield a level-shifted feedback voltage (e.g., Vllc shown in FIG. 4A or 4B) representing a load current (e.g., iload shown in FIG. 3) of the power supply circuit. At block 506, the power supply circuit adjusts the feedback voltage based on the level-shifted feedback voltage.

In some aspects, the feedback voltage may be generated via a voltage divider circuit (e.g., including resistive elements Rfb1 and Rfb2 shown in FIG. 4A). In some aspects, a resistive element (e.g., RLLC shown in FIG. 4A or FIG. 4B) may be coupled between the voltage divider circuit and an output voltage node (e.g., Vout node) of the power supply circuit. Adjusting the feedback voltage may include sinking a current from a node (e.g., node 460 of FIG. 4A or FIG. 4B) between the resistive element and the voltage divider circuit via a current source (e.g., current source 470). Performing the voltage level shift may include receiving the feedback voltage at an input of a voltage follower circuit (e.g., voltage follower circuit including current source 406 and transistor 404) to generate a voltage follower output voltage (e.g., voltage at node 430). Performing the voltage level shift may include sourcing a current (e.g., Ioffset) across a first resistive element (e.g., Roffset) to generate an offset voltage (e.g., voltage at node 432 of FIG. 4A or FIG. 4B). Performing the voltage level shift may include comparing (e.g., via amplifier 408) the offset voltage and the voltage follower output voltage to control the current source and generate the level-shifted feedback voltage. Controlling the current source may include controlling a transistor (e.g., transistor 402) having a source coupled to a second resistive element (e.g., resistive element RILLC) to generate the level-shifted feedback voltage at a node (e.g., node 440) between the transistor and the second resistive element.

In some aspects, performing the voltage level shift may include sourcing a current (e.g., Ioffset) across a resistive element (e.g., Roffset) to generate a voltage across the resistive element, wherein the level-shifted feedback voltage is less than the feedback voltage by an amount equal to the voltage across the resistive element.

Some aspects are directed towards a power supply circuit. The power supply circuit generally includes a power stage (e.g., power stage 302 of FIG. 3), and an inductive element (e.g., Lout shown in FIG. 3) coupled between the power stage and an output node (e.g., Vout node) of the power supply circuit. The power supply circuit may also include a feedback circuit (e.g., feedback circuit 380 shown in FIG. 3) coupled between the output node of the power supply circuit and a feedback node (e.g., Vc node shown in FIG. 4A or V_{ISNS} node shown in FIG. 4B), a level-shifter circuit (e.g., level-shifter circuit 494) having an input coupled to the feedback node, and a first current source (e.g., current source 470) coupled between the level-shifter circuit and a node (e.g., node 460) of the feedback circuit.

The power supply circuit may also include a resistive element (e.g., RLLC shown in FIG. 4A or FIG. 4B) coupled between a voltage divider circuit (e.g., including Rfb1 and Rfb2) of the feedback circuit and the output node. The node of the feedback circuit may be between the resistive element and the voltage divider circuit. The feedback circuit may also include an error amplifier (e.g., EA1 shown in FIG. 4A) having an input coupled to a voltage divider node (e.g., Vsns node) of the voltage divider circuit and a transistor (e.g., transistor 308) having a gate coupled to an output of the error amplifier, a source of the transistor being coupled to the feedback node. The power supply circuit may also include a second current source (e.g., current source 310) coupled between the source of the transistor and a reference potential node. The power supply circuit may also include a filter (e.g., filter 306) coupled to an output of the error amplifier.

In some aspects, the level-shifter circuit includes: a voltage follower circuit (e.g., including current source 406 and transistor 404) having an input coupled to the feedback node, a first transistor (e.g., transistor 412) having a gate coupled to the first current source, and amplifier (e.g., amplifier 408) having a first input coupled to an output (e.g., at node 430) of the voltage follower circuit and an output coupled to the first current source. The level-shifter circuit may also include a second current source (e.g., current source 410) and a first resistive element (e.g., Roffset) coupled between the first transistor and the second current source. The voltage follower circuit may be a source follower circuit, in some aspects. The voltage follower circuit may include a third current source (e.g., current source 406) and a second transistor (e.g., transistor 404) having a source coupled to the third current source. The output of the voltage follower circuit may be at a node (e.g., node 430) between the third current source and the second transistor. The second current source and the third current source may be configured to source the same offset current (e.g., Ioffset). The first current source may include a second transistor (e.g., transistor 402) having a gate coupled to the output of the amplifier, a source coupled to the gate of the first transistor, and a drain coupled to the node of the feedback circuit. The first current source may also include a second resistive element (e.g., resistive element RILLC) coupled to the source of the second transistor.

In some aspects, the power supply circuit comprises a gate driver (e.g., gate drive generator 314) having an input coupled to the feedback node and an output coupled to the power stage.

### Example Aspects

Aspect 1: A power supply circuit, comprising: a power stage coupled to an output node of the power supply circuit; a feedback circuit coupled to the output node of the power supply circuit and including a feedback node; a level-shifter circuit including an input coupled to the feedback node; and a first current source coupled between the level-shifter circuit and a node of the feedback circuit.

Aspect 2: The power supply circuit of Aspect 1, further comprising a resistive element coupled between a voltage divider circuit of the feedback circuit and the output node, wherein the node of the feedback circuit is between the resistive element and the voltage divider circuit.

Aspect 3: The power supply circuit of Aspect 2, wherein the feedback circuit further comprises: an error amplifier including an input coupled to a voltage divider node of the voltage divider circuit; and a transistor including a gate coupled to an output of the error amplifier, a source of the transistor being coupled to the feedback node.

Aspect 4: The power supply circuit of Aspect 3, further comprising a second current source coupled between the source of the transistor and a reference potential node.

Aspect 5: The power supply circuit of Aspect 3 or 4, further comprising a filter coupled to an output of the error amplifier.

Aspect 6: The power supply circuit according to any of Aspects 1-5, wherein the level-shifter circuit comprises: a voltage follower circuit including an input coupled to the feedback node; a first transistor including a gate coupled to the first current source; an amplifier including a first input coupled to an output of the voltage follower circuit and an output coupled to the first current source; a second current source; and a first resistive element coupled between the first transistor and the second current source.

Aspect 7: The power supply circuit of Aspect 6, wherein the voltage follower circuit comprises: a third current source; and a second transistor including a source coupled to the third current source, wherein the output of the voltage follower circuit is at a node between the third current source and the second transistor.

Aspect 8: The power supply circuit of Aspect 7, wherein the second current source and the third current source are configured to source an offset current.

Aspect 9: The power supply circuit according to any of Aspects 6-8, wherein the first current source comprises: a second transistor including a gate coupled to the output of the amplifier, a source coupled to the gate of the first transistor, and a drain coupled to the node of the feedback circuit; and a second resistive element coupled to the source of the second transistor.

Aspect 10: The power supply circuit according to any of Aspects 1-9, further comprising an inductive element coupled between the power stage and the output of the power supply circuit.

Aspect 11: The power supply circuit according to any of Aspects 1-10, further comprising a gate driver including an input coupled to the feedback node and an output coupled to the power stage.

Aspect 12: The power supply circuit according to any of Aspects 1-11, wherein: the feedback circuit is configured to generate a feedback voltage at the feedback node; the level-shifter circuit is configured to perform a voltage level shift based on the feedback voltage to yield a level-shifted feedback voltage representing a load current of the power supply circuit; and the first current source is configured to sink a current to adjust the feedback voltage based on the level-shifted feedback voltage.

Aspect 13: The power supply circuit of Aspect 12, wherein: the feedback circuit comprises a voltage divider circuit; the power supply circuit further comprises a resistive element coupled between the voltage divider circuit and the output node of the power supply circuit; and the current is sunk from a node between the resistive element and the voltage divider circuit to adjust the feedback voltage.

Aspect 14: A method for power supply control, comprising: generating a feedback voltage based on an output voltage of a power supply circuit; performing a voltage level shift based on the feedback voltage to yield a level-shifted feedback voltage representing a load current of the power supply circuit; and adjusting the feedback voltage based on the level-shifted feedback voltage.

Aspect 15: The method of Aspect 14, wherein: a resistive element is coupled between a voltage divider circuit and an output voltage node of the power supply circuit; and adjusting the feedback voltage comprises sinking a current from a node between the resistive element and the voltage divider circuit via a current source.

Aspect 16: The method of Aspect 15, wherein performing the voltage level shift comprises: receiving the feedback voltage at an input of a voltage follower circuit to generate a voltage follower output voltage; sourcing a current across a first resistive element to generate an offset voltage; and comparing, via an amplifier, the offset voltage and the voltage follower output voltage to control the current source and generate the level-shifted feedback voltage.

Aspect 17: The method of Aspect 16, wherein controlling the current source comprises controlling a transistor including a source coupled to a second resistive element to generate the level-shifted feedback voltage at a node between the transistor and the second resistive element.

Aspect 18: The method according to any of Aspects 14-17, wherein performing the voltage level shift comprises sourcing a current across a resistive element to generate a voltage across the resistive element, wherein the level-shifted feedback voltage is less than the feedback voltage by an amount equal to the voltage across the resistive element.

Aspect 19: A load line compensation (LLC) circuit, comprising: a level-shifter circuit configured to perform a voltage level shift based on a feedback voltage for a power supply circuit to yield a level-shifted feedback voltage representing a load current of the power supply circuit; and a current source configured to adjust the feedback voltage based on the level-shifted feedback voltage.

Aspect 20: The LLC circuit according to any of Aspects 14-19, further comprising: a resistive element coupled between a voltage divider circuit and an output voltage node of the power supply circuit, wherein, to adjust the feedback voltage, the current source is configured to sink a current from a node between the resistive element and the voltage divider circuit via a current source.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation, and details of the methods and apparatus described above without departing from the scope of the claims.

What is claimed is:

1. A power supply circuit, comprising:
a power stage coupled to an output node of the power supply circuit;
a feedback circuit coupled to the output node of the power supply circuit and including a feedback node;
a level-shifter circuit including an input coupled to the feedback node; and
a first current source coupled between the level-shifter circuit and a node of the feedback circuit.

2. The power supply circuit of claim 1, further comprising a resistive element coupled between a voltage divider circuit of the feedback circuit and the output node, wherein the node of the feedback circuit is between the resistive element and the voltage divider circuit.

3. The power supply circuit of claim 2, wherein the feedback circuit further comprises:
an error amplifier including an input coupled to a voltage divider node of the voltage divider circuit; and
a transistor including a gate coupled to an output of the error amplifier, a source of the transistor being coupled to the feedback node.

4. The power supply circuit of claim 3, further comprising a second current source coupled between the source of the transistor and a reference potential node.

5. The power supply circuit of claim 3, further comprising a filter coupled to an output of the error amplifier.

6. The power supply circuit of claim 1, wherein the level-shifter circuit comprises:
a voltage follower circuit including an input coupled to the feedback node;
a first transistor including a gate coupled to the first current source;
an amplifier including a first input coupled to an output of the voltage follower circuit and an output coupled to the first current source;
a second current source; and
a first resistive element coupled between the first transistor and the second current source.

7. The power supply circuit of claim 6, wherein the voltage follower circuit comprises:
a third current source; and
a second transistor including a source coupled to the third current source, wherein the output of the voltage follower circuit is at a node between the third current source and the second transistor.

8. The power supply circuit of claim 7, wherein the second current source and the third current source are configured to source an offset current.

9. The power supply circuit of claim 6, wherein the first current source comprises:
a second transistor including a gate coupled to the output of the amplifier, a source coupled to the gate of the first transistor, and a drain coupled to the node of the feedback circuit; and
a second resistive element coupled to the source of the second transistor.

10. The power supply circuit of claim 1, further comprising an inductive element coupled between the power stage and the output of the power supply circuit.

11. The power supply circuit of claim 1, further comprising a gate driver including an input coupled to the feedback node and an output coupled to the power stage.

12. The power supply circuit of claim 1, wherein:
the feedback circuit is configured to generate a feedback voltage at the feedback node;
the level-shifter circuit is configured to perform a voltage level shift based on the feedback voltage to yield a level-shifted feedback voltage representing a load current of the power supply circuit; and
the first current source is configured to sink a current to adjust the feedback voltage based on the level-shifted feedback voltage.

13. The power supply circuit of claim 12, wherein:
the feedback circuit comprises a voltage divider circuit;
the power supply circuit further comprises a resistive element coupled between the voltage divider circuit and the output node of the power supply circuit; and
the current is sunk from a node between the resistive element and the voltage divider circuit to adjust the feedback voltage.

14. A method for power supply control, comprising:
generating a feedback voltage based on an output voltage of a power supply circuit;
performing a voltage level shift based on the feedback voltage to yield a level-shifted feedback voltage representing a load current of the power supply circuit; and
adjusting the feedback voltage based on the level-shifted feedback voltage.

15. The method of claim 14, wherein:
a resistive element is coupled between a voltage divider circuit and an output voltage node of the power supply circuit; and
adjusting the feedback voltage comprises sinking a current from a node between the resistive element and the voltage divider circuit via a current source.

16. The method of claim 15, wherein performing the voltage level shift comprises:
receiving the feedback voltage at an input of a voltage follower circuit to generate a voltage follower output voltage;
sourcing a current across a first resistive element to generate an offset voltage; and
comparing, via an amplifier, the offset voltage and the voltage follower output voltage to control the current source and generate the level-shifted feedback voltage.

17. The method of claim 16, wherein controlling the current source comprises controlling a transistor including a source coupled to a second resistive element to generate the level-shifted feedback voltage at a node between the transistor and the second resistive element.

18. The method of claim 14, wherein performing the voltage level shift comprises sourcing a current across a resistive element to generate a voltage across the resistive element, wherein the level-shifted feedback voltage is less than the feedback voltage by an amount equal to the voltage across the resistive element.

19. A load line compensation (LLC) circuit, comprising:
a level-shifter circuit configured to perform a voltage level shift based on a feedback voltage for a power supply circuit to yield a level-shifted feedback voltage representing a load current of the power supply circuit; and
a current source configured to adjust the feedback voltage based on the level-shifted feedback voltage.

20. The LLC circuit of claim 14, further comprising:
a resistive element coupled between a voltage divider circuit and an output voltage node of the power supply circuit, wherein, to adjust the feedback voltage, the current source is configured to sink a current from a node between the resistive element and the voltage divider circuit via a current source.
